(19) United States
(12) Patent Application Publication
(10) Pub. No.: US 2008/0099772 A1
(43) Pub. Date: May 1, 2008

(54) Light emitting diode matrix

(76) Inventors: Geoffrey Wen-Tai Shuy, Ma On Shan (HK); Enboa Wu, Irvine, CA (US); Ming Lu, Sijhih City (TW)

Correspondence Address: FISH & RICHARDSON PC, P.O. BOX 1022, MINNEAPOLIS, MN, 55440-1022, US

(21) Appl. No.: 11/589,705

(22) Filed: Oct. 30, 2006

(51) Int. Cl. H01L 33/00; H01L 29/207

(52) U.S. Cl. 257/88; 257/93

(57) ABSTRACT

A light source includes a light emitting diode (LED) module having a continuous substrate, a layer of n-type semiconductor material formed above the substrate, and a layer of p-type semiconductor material formed above the n-type semiconductor material. A p-n junction is formed between the p-type and n-type semiconductor materials. The p-type and n-type semiconductor materials are selected to emit light at the p-n junction when an electric current flows through the p-n junction. The LED module includes a plurality of electric contacts connected to the p-type semiconductor material, and at least one electric contact connected to the n-type semiconductor material. The electric contacts are configured to pass electric current through a plurality of regions in the p-n junction such that the plurality of regions have higher electric current densities and emit light brighter than areas outside of the plurality of regions.

### BACKGROUND

This invention relates to a failure tolerable light emitting diode (LED) light source using an LED matrix.

A light emitting diode (LED), such as gallium nitride (GaN) based LED, includes one or more layers of n-type semiconductor material (e.g., n-GaN) and one or more layers of p-type semiconductor material (e.g., p-GaN) that are deposited on a substrate (e.g., a sapphire substrate) using metal-organic vapor deposition, molecular beam epitaxy, or another deposition technique. A p-n junction is formed between the n-type and p-type semiconductor materials. When a forward bias voltage is applied to the LED, electrons combine with holes at a region near the p-n junction, in which the electrons transition from a higher energy state to a lower energy state, releasing energy in the form of photons. The wavelength of the light emitted by the LED depends on the band gap energy of the n-type and p-type semiconductor materials.

Commercially available LEDs are typically packaged LEDs, each including, e.g., an LED chip (which includes the substrate, the n-type semiconductor material layer(s) and p-type semiconductor material layer(s)), electrodes on the chip for electrical connection to the n-type and p-type layers and to provide pads for electrical connection to the electrodes of the package, electrodes for conducting an electric current from outside the packing to the LED chip, a heat sink for dissipating heat generated from the LED chip, a reflector or focusing lens for reflecting or focusing light emitted from the LED chip, and a transparent or semitransparent housing to protect the various components. In some examples, enhancement of the brightness of a packaged LED can be achieved by increasing the emission efficiency of the LED chip, increasing the area of the p-type and n-type semiconductor materials, and improving the heat dissipation and light reflection/focusing mechanisms. Multiple packaged LEDs can be connected in an array to increase brightness. Examples of packaged LED arrays can be found in flashlights and traffic lights.

When a light source uses a single, large, high brightness LED chip, the light source has little or no failure tolerance. When the single LED chip fails, the light source fails. When a light source uses several packaged LEDs connected in series, the light source also has little or no failure tolerance. When any of the series-connected packaged LEDs fails, the failed LED becomes an open circuit and electric current to the other packaged LEDs is cut off, so the light source fails and cannot generate any light output.

### SUMMARY

In a general aspect, parallel arrangements or a series of parallel arrangements of light-emitting devices fabricated on a common substrate is tolerant on isolated device failures while maintaining substantially unchanged light output. The light-emitting devices are operated with the common substrate intact. The light emitting devices can be, e.g., light emitting diodes.

In another general aspect, in order to provide high light output and also maintain a low probability of failure, a parallel arrangement or a series-parallel arrangement of light-emitting devices are fabricated and electrically interconnected on a single integrated circuit. The light emitting devices can be, e.g., light emitting diodes.

In one aspect, in general, an apparatus includes a light emitting diode (LED) module or matrix having a continuous substrate, a layer of n-type semiconductor material formed above the substrate, and a layer of p-type semiconductor material formed above the n-type semiconductor material. A p-n junction is formed between the p-type and n-type semiconductor materials. The p-type and n-type semiconductor materials are selected to emit light at the p-n junction when an electric current flows through the p-n junction. The LED module includes a plurality of electric contacts connected to the p-type semiconductor material, and at least one electric contact connected to the n-type semiconductor material. The electric contacts are configured to pass electric current through a plurality of regions in the p-n junction such that the plurality of regions have higher electric current densities and emit light brighter than areas outside of the plurality of regions.

Implementations of the apparatus may include one or more of the following features. The electric contacts connected to the p-type semiconductor material can be arranged in a plurality of columns and rows such that the LED module form an area light source. In some examples, the apparatus includes a circuit board having conducting lines, the LED module being flip-chip bonded to the circuit board in which the electric contacts are coupled to the conducting lines. In some examples, the apparatus includes a circuit board having conducting lines, the electric contacts of the LED module being coupled to the conducting lines on the circuit board through bonding wires. The apparatus can include a substantially transparent conducting layer that connects two or more of the electric contacts that are connected to the p-type semiconductor material.

The layer of p-type material can include distinct regions, each distinct region of the p-type material and a portion of the n-type material in combination forming one of the LED chips. Each chip is not necessarily a separate component. For example, the n-type material of different chips may be connected. For example, use of the term ‘chip’ may connote a logical region of a fabricated integrated circuit that may not have a defined boundary on the circuit. The LED module can include LED chips that are connected in series. The layer of p-type material can include distinct regions, each distinct region of the p-type material and a distinct region of the n-type material in combination forming one of the LED chips. The LED module can include an insulation material to insulate an edge of the n-type material from an edge of the p-type material to reduce leakage current that flows from the p-type material to the n-type material through the edges of the materials. The LED chips can be connected in series using at least one of bonding wires and conducting layers. The LED module can include at least two LED chips that are connected in parallel.

The p-type material between LED chips can be etched through, and the n-type material between the LED chips can be partially etched to expose the n-type material. The n-type material belonging to different LED chips can form a continuous layer. The LED module can include an insulation material to insulate the n-type material from the p-type material at the edges of the n-type and p-type materials exposed by the etching. The at least two LED chips can be connected in parallel using at least one of bonding wires and conducting layers. The n-type semiconductor material can be deposited on the substrate.

In another aspect, in general, an apparatus includes a light emitting diode (LED) module that includes a continuous substrate, a layer of p-type semiconductor material formed above the substrate, and a layer of n-type semiconductor material formed above the p-type semiconductor material. A p-n junction is formed between the p-type and n-type semiconductor materials. The p-type and n-type semiconductor materials are selected to emit light at the p-n junction when an electric current flows through the p-n junction. The LED module includes a plurality of electric contacts connected to the n-type semiconductor material, and at least one electric contact connected to the p-type semiconductor material. The electric contacts are configured to pass electric current through a plurality of regions in the p-n junction such that the plurality of regions have higher electric current densities and emit light brighter than areas outside of the plurality of regions.

In another aspect, in general, a light source includes a circuit board and a plurality of light emitting diode (LED) modules mounted on the circuit board. Each LED module includes a plurality of LED chips that are positioned adjacent to each other and fabricated on a common substrate that is a continuous piece of material. The light source includes a housing to enclose the circuit board and the LED modules.

Implementations of the apparatus may include one or more of the following features. The light source can comply with MR-16 standard.

In another aspect, in general, an apparatus includes a first array of LED chips fabricated on a common substrate, in which the common substrate is a continuous piece of material. Each LED chip forms a light source and can include a layer of p-type semiconductor material, a layer of n-type semiconductor material coupled to the p-type material to form a p-n junction, and an electric contact connected to the p-type material or an electric contact connected to the n-type material. The LED chips of the array can be connected in parallel such that the n-type material of the LED chips are electrically coupled together, and the p-type material of the LED chips are electrically coupled together.

Implementations of the apparatus may include one or more of the following features. The apparatus can include a circuit board having conducting lines, the first array of LED chips being flip-chip bonded to the circuit board in which the conducting pads of the LED chips are electrically coupled to the conducting lines. The apparatus can include a second array of LED chips fabricated on a common substrate that is a continuous piece of material, the second array of LED chips being connected to the first array of LED chips in series.

In another aspect, in general, an apparatus includes a first group of light emitting diode (LED) modules connected in parallel, in which each LED module includes a plurality of LED chips connected in series. The plurality of LED chips in each LED module are fabricated on a common substrate, the common substrate being intact without being divided to separate the LED chips. For each of the LED modules, the LED chips of the module emit light simultaneously when an electric current passes through the LED module.

Implementations of the apparatus may include one or more of the following features. The plurality of LED chips can be connected in series by connecting an n-type semiconductor material of one of the LED chips to a p-type semiconductor material of another of the LED chips using at least one of bonding wires and conducting layers. The apparatus can include a second group of LED modules connected in parallel, each LED module in the second group including a plurality of LED chips connected in series, the second group being connected in series to the first group. The apparatus can include an elongated substrate, the plurality of LED chips in the first group being positioned along a lengthwise direction on the first elongated substrate to form a line light source.

In another aspect, in general, an apparatus includes a first group of LED modules that are connected in parallel, each LED module including a plurality of LED chips connected in parallel. The plurality of LED chips of the LED module are fabricated on a common substrate, in which the common substrate is intact without being divided to separate the LED chips. The plurality of LED chips emit light simultaneously when an electric current passes through the LED module.

Implementations of the apparatus may include one or more of the following features. The apparatus can include an elongated substrate, in which the plurality of LED chips in the first group of LED modules are positioned along a lengthwise direction on the elongated substrate to form a line light source. The apparatus can include a second group of LED modules that are connected in parallel, in which each LED module includes a plurality of LED chips connected in parallel, the second group being connected in series with the first group.

In another aspect, in general, a lighting device includes a circuit board having signal lines, and a light emitting diode (LED) module mounted on the circuit board to receive electric power from the signal lines. The LED module includes a plurality of LED chips fabricated on a common substrate, in which the common substrate is intact without being cut to separate the LED chips. Each LED chip forms a light source, in which the LED chips are connected in series or parallel. The LED module also includes a controller to control the LED module.

Implementations of the apparatus may include one or more of the following features. The LED chips of the LED modules can be arranged in a plurality of rows and columns to form an area light source.

In another aspect, in general, a method includes fabricating a light emitting diode (LED) module having a plurality of LED chips on a continuous substrate. The LED chips are fabricated according to a process that includes fabricating a layer of n-type semiconductor material above the substrate, and fabricating a layer of p-type semiconductor material above the n-type semiconductor material. A p-n junction is formed between the p-type and n-type materials, the p-type and n-type materials selected to emit light at the p-n junction when an electric current flows through the p-n junction. The process includes fabricating a plurality of electric contact pads connected to the p-type material, and fabricating at least one electric contact pad connected to the n-type material. The electric contact pads connected to the p-type and n-type materials are configured to pass electric current through a plurality of regions in the p-n junction such that the plurality of regions have higher electric current densities and emit light brighter than areas outside of the plurality of regions.

Implementations of the method may include one or more of the following features. In some examples, the method can include flip-chip bonding the LED module to a circuit board having conducting lines by coupling the electric contact pads to conducting lines on the circuit board. In some examples, the method can include coupling electric contact pads of the LED module to conducting lines on a circuit board through bonding wires. The LED module can include separating the p-type materials of different LED chips by etching portions of the p-type material to expose the underlying n-type material, the n-type material belonging to different LED chips of the LED module being a continuous layer.

Fabricating the LED module can include connecting the LED chips in parallel. Fabricating the LED module can include fabricating an insulation material positioned between the exposed n-type material and an edge of the p-type material. The insulation material can be configured to prevent current from flowing from the p-type material to the n-type material through the edge of the p-type material. Fabricating the LED module can include separating the p-type and n-type materials of different LED chips by etching portions of the p-type and n-type materials to expose the underlying substrate. Fabricating the LED module can include connecting the LED chips in series. The method can include fabricating an insulation material positioned adjacent to the edges of the n-type and p-type materials that are exposed by the etching. Fabricating the layer of n-type semiconductor material above the substrate can include depositing the n-type semiconductor material on the substrate.

In another aspect, in general, a method of operating a lighting device includes passing an electric current through a plurality of light emitting diode (LED) chips that are fabricated on a common substrate that is a continuous piece of material. Each LED chip forms a light source, in which the LED chips are connected in series or parallel, and the plurality of LED chips form a line light source or an area light source. The method includes regulating the electric current to control a brightness of light emitted by the LED chips.

Implementations of the method may include one or more of the following features. Passing an electric current through a plurality of LED chips includes passing the electric current through separated regions of a layer of p-type semiconductor material and different portions of a continuous layer of n-type semiconductor material.

In another aspect, in general, a method includes generating light from a plurality of light emitting diode (LED) chips that are positioned adjacent to each other and fabricated on a common substrate that is intact without being cut to separate the LED chips.

Implementations of the apparatus may include one or more of the following features. The plurality of LED chips include a layer of p-type semiconductor material divided into separate regions and a continuous layer of n-type semiconductor material.

In another aspect, in general, a light source includes a series of parallel arrangements of LED chips that are fabricated on a common substrate. Each LED chip includes a layer of p-type semiconductor material and a layer of n-type semiconductor material, in which a p-n junction is formed between the p-type and n-type materials. A first group of parallel connected LED chips are connected in series with a second group of parallel connected LED chips. The first and second group of LED chips are fabricated on a continuous substrate that is not cut when the LED chips are in operation. The p-type material and the n-type material can be etched to isolate the first group of LED chips from the second group of LED chips.

Implementations of the light source may include one or more of the following features. The LED chips within the first group can be connected in parallel by wire bonding or conducting layers. The first group of parallel connected LED chips can be connected in series with the second group of parallel connected LED chips by using either wire bonding or conducting layers. The p-type material and the n-type material can be etched to isolate the LED chips within the first (and/or second) group of LED chips, so that when one of the LED chips fail, the failed LED chip is isolated from the rest of the LED chips and does not affect the operation of the remaining functional LED chips. Insulation material can be provided at the edges of the p-type or n-type material to prevent leakage current.

Aspects can have one or more of the following advantages. The LED module or matrix can have a higher defect or failure tolerance, higher reliability, higher emitting efficiency, better thermal dissipation, and lower cost as compared to a single high brightness LED. By not cutting the substrate to separate individual LED chips, expensive cutting tools (e.g., diamond saw) can be avoided, and the cost of fabricating a large area light source having an array of LED chips can be reduced. In some examples, by etching the p-type and n-type layers to isolate the LED chips on the common substrate, failure of one LED chip will not affect the operation of other LED chips. By using insulation material at edges of the p-type and n-type materials to prevent or reduce leakage current, the LED module or matrix can have a more uniform brightness.

Other features and advantages of the invention are apparent from the following description, and from the claims.

### DESCRIPTION OF DRAWINGS

FIG. 1 is a top view of an LED module.

FIG. 2 is a cross sectional diagram of the LED module of FIG. 1.

FIG. 3 is a schematic diagram of an equivalent circuit of the LED module of FIG. 1.

FIG. 4 is a diagram of a large area light source.

FIG. 5 is a diagram of LED modules fabricated on a common substrate

FIG. 6 is a diagram of a large area LED light source.

FIG. 7 is a schematic diagram of an equivalent circuit of the large area LED light source of FIG. 6.

FIG. 8 is a cross sectional diagram of an LED module.

FIG. 9 is a top view of the LED module of FIG. 8.

FIG. 10A is a diagram of an LED matrix.

FIG. 10B is a diagram of the LED chips of an LED module.

FIG. 11A is a diagram of an LED matrix.

FIG. 11B is a diagram of the LED chips of an LED module.

FIG. 12 is a diagram of LED modules each having LED chips connected in series.

FIG. 13 is a cross sectional diagram of an LED module.

FIG. 14 is a diagram of an LED matrix.

FIG. 15 is a diagram of an equivalent circuit of the LED matrix of FIG. 14.

FIG. 16 is a top view of an LED module.

FIGS. 17 and 18 are diagrams of LED modules.

### DESCRIPTION

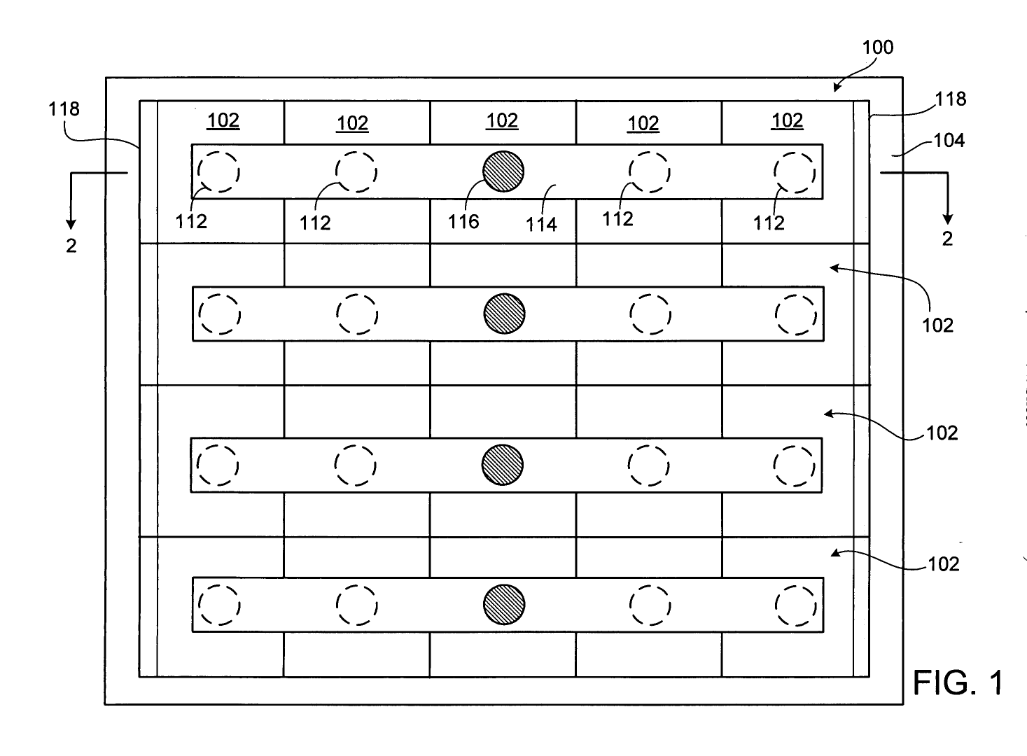

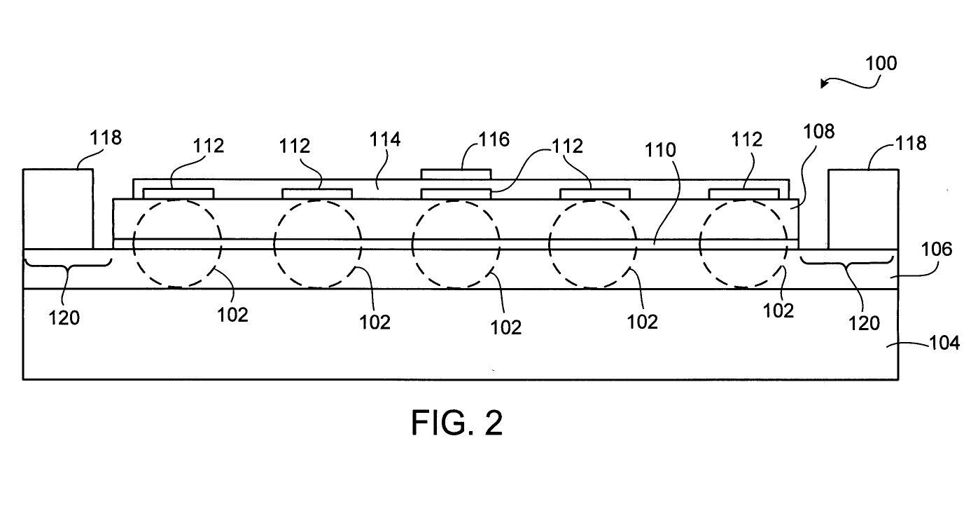

FIG. 1 is a top view of an LED module 100 that includes twenty LED chips 102 that are fabricated on a common substrate 104. FIG. 2 is a cross sectional diagram of the LED module 100. Referring to FIGS. 1 and 2, the LED module 100 includes four rows of LED chips 102, each row including five LED chips 102. Within the LED module 100, the LED chips 102 are connected in parallel. An LED light source can include multiple LED modules 100 that are connected in parallel or in series. This allows the LED light source to be tolerable to failure of individual LED chips 102 (resulting in an open circuit at the failed LED chip). Even when some of the LED chips 102 fail, the total light output of the LED light source does not drop significantly. Because each LED chip 102 is small, and the LED chips 102 are densely packed together, one LED chip 102 that failed may not be noticeable to the user. Even if a few LED chips 102 fail, when the failed LED chips 102 are spaced apart, the user may still not notice the failed LED chips 102. The probability of a number of adjacent LED chips 102 fail at the same time is small. By comparison, in a conventional LED light source that includes an array of packaged LEDs in which the LED chips are individually packaged, each packaged LED has a larger size, so even a single failed packaged LED would be noticeable to the user.

In this description, each chip is not necessarily a separate component. For example, use of the term ‘chip’ may connote a logical region of a fabricated integrated circuit that may not have a defined boundary on the circuit.

The twenty LED chips 102 are not cut and separated from one another. Rather, the p-type semiconductor material 108 of the twenty LED chips 102 form a continuous layer. Similarly, the n-type semiconductor material 106 of the twenty LED chips 102 form a continuous layer. By not cutting and separating the LED chips 102, the manufacturing process for a light source that uses the LED module 100 can be made simpler and cheaper. Aligning the LED chips with other components of the light source, such as conducting lines, can be made simpler. Because the amount of light output per unit area is higher, the light intensity of the LED module 100 can be higher than a conventional LED light source that uses an array of packaged LEDs.

Several LED modules 100 may be fabricated on a wafer (not shown). The wafer may be cut to separate the LED modules 100, but each LED module 100 is not cut to separate the LED chips 102.

Referring to FIGS. 1 and 2, the LED chips 102 are fabricated by depositing a layer of n-type semiconductor material 106 (e.g., n-GaN) on the substrate 104 (e.g., made of sapphire (Al₂O₃ crystal) or silicon carbide (SiC)), and depositing a layer of p-type semiconductor material 108 (e.g., p-GaN) on the n-type semiconductor material 106. One or more layers of p-n junctions 110 are formed between the n-type and p-type semiconductor materials 106 and 108. The p-n junction 110 emits light when current flows through.

A metal contact pad, referred to as a P-pad 112, is formed above the p-type semiconductor material 108 of each LED chip 102. A transparent or semi-transparent conducting layer 114 is formed above the P-pad 112 and connects five P-pads 112 of a row. A metal contact pad, referred to as a P-pad 116, is formed above each conducting layer 114.

In this description, when a layer or component X of a device is said to be above another layer or component Y, it is meant that X is above Y when the device is positioned in the orientation shown in the figure. The device may be used in different orientations, such as being flipped over, then X may become below Y. Similarly, terms such as “upward,” “downward,” “left,” and “right” are used for convenience of describing the positions or orientations of the layers and components of a device, and are not meant to limit the device to be used in a particular position or orientation.

The p-type semiconductor material 108 is etched at the edges of the LED module 100 to expose portions 120 (see FIG. 2) of the n-type semiconductor material 106. Metal contact pads, referred to as N-pads 118, are formed above the exposed portions 120 of the n-type semiconductor material 106. The P-pad 116 and the N-pad 118 are used to connect to external components, such as power lines, other electronic devices (e.g., zener diode for electro-static discharge protection), or other LED modules 100.

When the LED module 100 is in operation, electric current flows from the P-pad 116 to the metal conducting layer 114 to the P-pads 112. The current then flows from the P-pads 112 through the p-type semiconductor material, the p-n junction 110, the n-type semiconductor material 106, and to the N-pads 118. The regions directly below the P-pads 112 have higher current densities than the regions between the P-pads 112, so the regions directly below the P-pads 112 emit light having higher intensities. The LED module 100 is described as having twenty LED chips 102 because there are twenty regions that emit light with higher intensities.

The arrangement of P-pads 112, conducting layers 114, P-pads 116, and N-pads 118 provide better distribution of electric current in the LED module 100, and better heat dissipation, as compared to a single large LED (having an area comparable to the LED module 100) having a single P-pad and a single N-pad. Because the twenty LED chips 102 are fabricated on the same substrate 104, the LED chips 102 have similar light emittance characteristics, resulting in a light source having a more uniform brightness across the area of the LED module 100, as compared to using twenty LED chips 102 that are fabricated on different substrates or on different regions of a substrate.

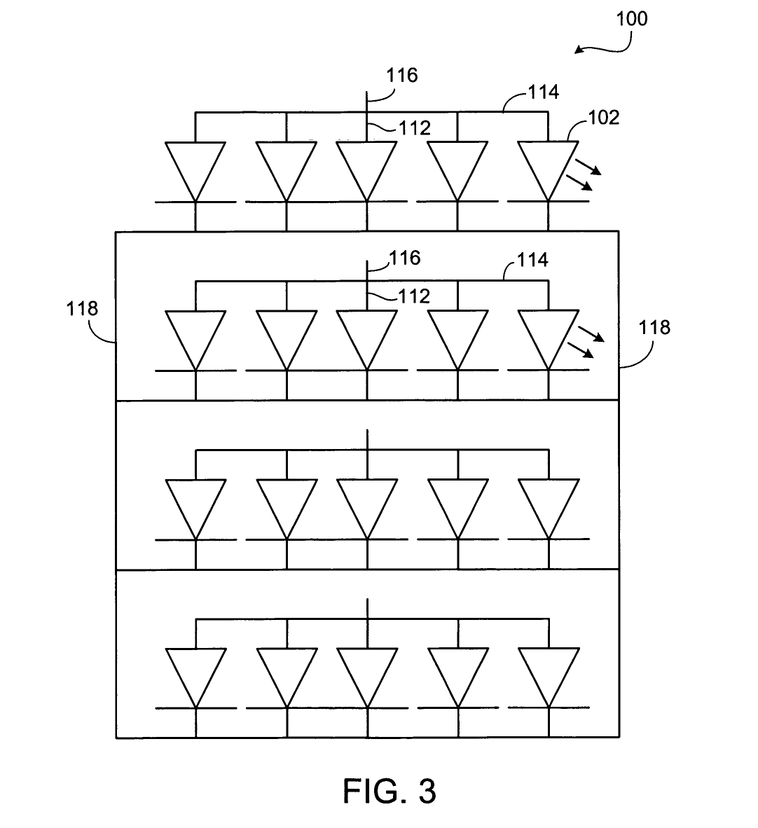

FIG. 3 is a schematic diagram of an equivalent circuit of the LED module 100.

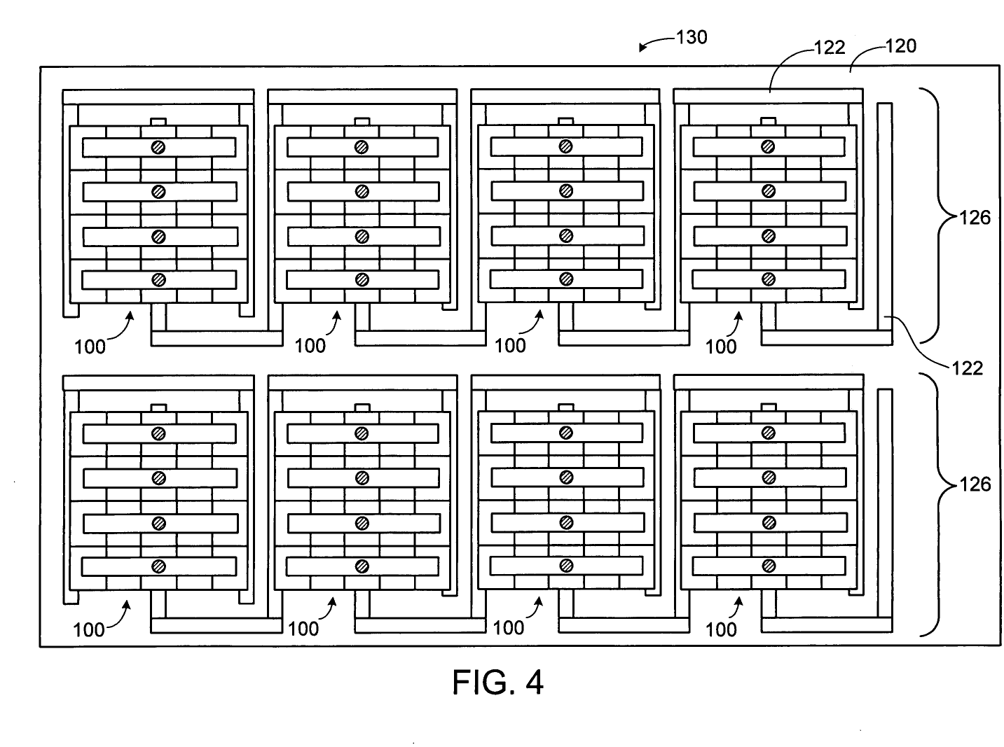

FIG. 4 is a diagram of an example of a large area light source 130 that includes a circuit board 120 and eight LED modules 100 that are flip-chip bonded to the circuit board 120. The LED modules 100 are flipped and the P-pads 118 and N-pads 116 are bonded to conducting lines 122 on the circuit board 120. In FIG. 4, the substrate 104 is on top while the P-pads 116 and N-pads 118 face downward and connect to the conducting lines 122.

The large area light source 130 includes two groups 126 of LED modules 100. Within each group 126, the LED modules 100 are connected in series, in which the P-pad 116 of one LED module 100 is connected to the N-pad 118 of another LED module 100. The two groups 126 can be connected such that they emit light simultaneously. The two groups 126 can also be used as two light sources that can be individually controlled. For example, the light source 130 can be constructed into a light source having two brightness settings. In the lower brightness setting, only one group 126 emits light, and in the higher brightness setting, both groups 126 emit light.

The large area light source 130 is fault tolerant because in each LED module 100, each LED chip 102 is connected in parallel with one or more other LED chips 102, and therefore an open circuit fault (due to failure of one LED chip) does not prevent other LED chips from functioning. The probability that all of the LED chips 102 within the same LED module 100 fail prematurely is low. When used with a constant current source, if one LED chip 102 within the LED module 100 fails (e.g., becomes open circuit), the amount of current flowing into the remaining LED chips 102 in the LED module 100 increases, so each of the remaining LED chips 102 becomes brighter, offsetting the loss of light from the failed LED chip 102. Due to the non-linear current-voltage (I-V) characteristics of the LED chips 102, the total brightness produced by the LED module 100 after one LED chip 102 fails may become slightly higher than the original brightness of the LED module 100.

For a given type of LED chips 102, due to the non-linear I-V characteristics of the LED chips 102, the voltage drop across each LED chip 102 under normal operating conditions is substantially constant even when the current flowing through the LED chip increases. For example, if the current flowing through each LED chip increases p %, the voltage across each LED chip increases less than 0.1*p %. The number of LED modules 100 that are connected in series can be determined by the voltage source to be applied to the large area light source 130. For example, if the voltage drop across each LED chip 102 is about 3V, then eight LED chips 102 connected in series would result in a voltage drop of about 24V. Each group 126 of the large area light source 130 includes four LED modules 100 connected in series, so two groups 126 connected in series would result in a voltage drop of about 24V, suitable for connecting to a 24V light bulb socket.

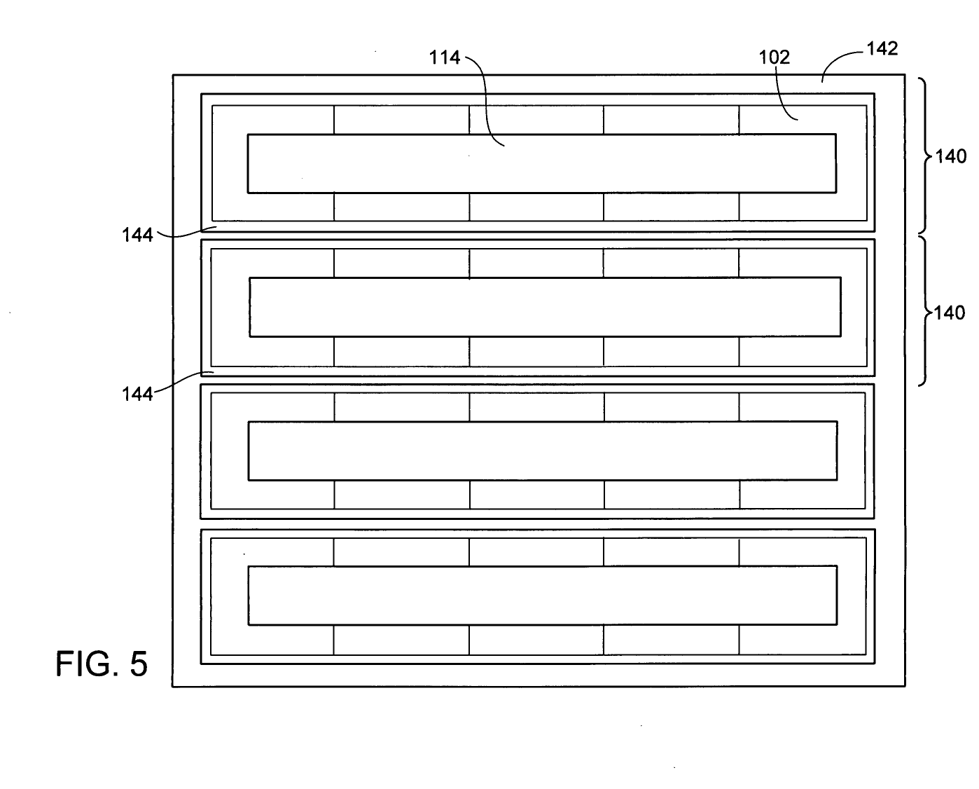

FIG. 5 shows four LED modules 140 that are fabricated on a common substrate 142. Each LED module 140 includes five LED chips 102 that are connected in parallel, similar to a row of LED chips 102 shown in FIG. 1. A difference between an LED module 140 in FIG. 5 and a row of LED chips 102 in FIG. 1 is that, in FIG. 5, each LED module 140 is separated from the other LED modules 140 by etching away the n-type semiconductor material 106 between the LED modules 140. Later, the LED modules 140 can be separated from each other by cutting and separating the substrate 142.

In each LED module 140, the p-type semiconductor material 108 is etched on four edges of the LED module 140 to expose portions of the n-type semiconductor material 106. Metal conducting pads, referred to as N-pads 144, are formed above part of the exposed portions of the n-type semiconductor material 106. In the example of FIG. 5, the N-pads 144 form a continuous loop that surrounds the LED module 140. This provides better electric current distribution when the LED module 140 is in operation.

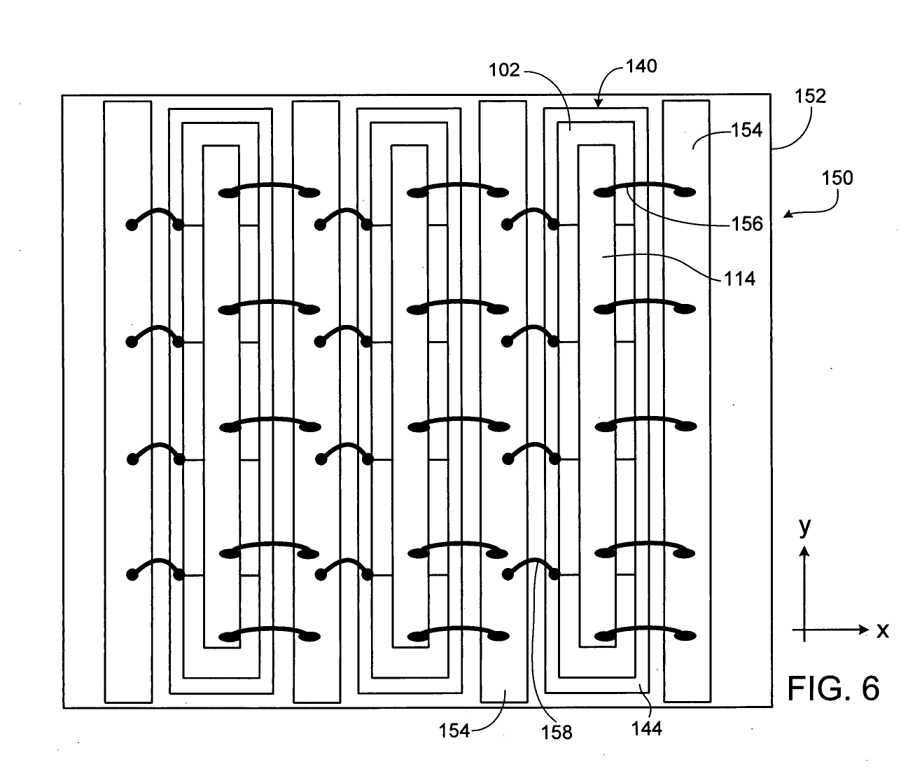

Referring to FIG. 6, a large area LED light source 150 includes three LED modules 140 that are connected in series and spaced apart in an x-direction. Each LED module 140 includes five LED chips 102 that are positioned along a y-direction. The LED modules 140 are mounted on a circuit board 152 having conducting lines 154 that extend in the y-direction.

For each LED module 140, multiple bonding wires 156 extend in the x-direction to connect the conducting layer 114 to a conducting line 154 positioned to the right the LED module 140. Multiple bonding wires 158 extend in the x-direction to connect the N-pad 144 to another conducting line 154 positioned to the left of the LED module 140. The multiple bonding wires 156 and 158 allow electric current to spread more evenly on the conducting layer 114 and the N-pad 144 so that the current flowing to each LED chip 102 in the same module 140 will be substantially the same. Each LED module 140 forms a line light source that extends in the y-direction.

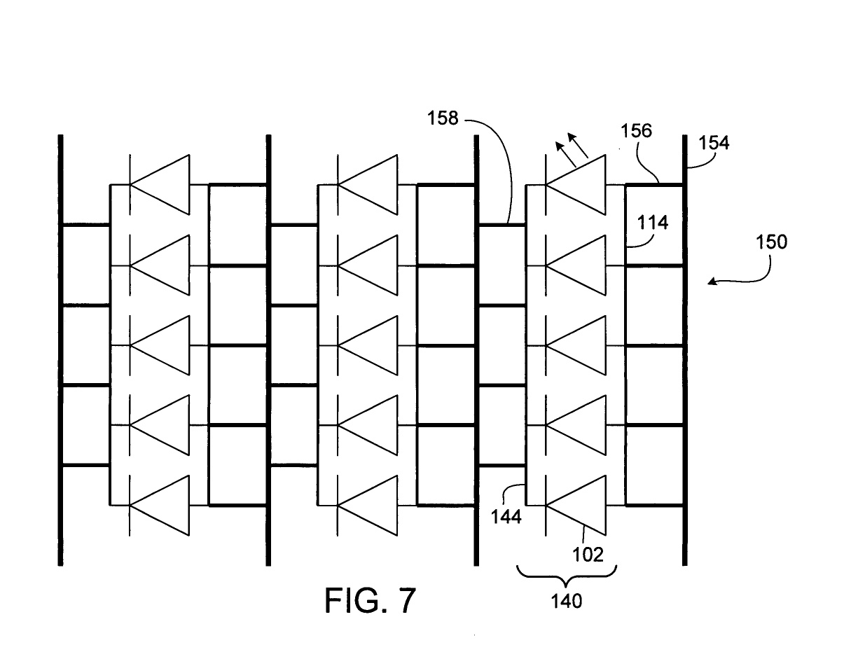

FIG. 7 is a schematic diagram of an equivalent circuit of the large area LED light source 150.

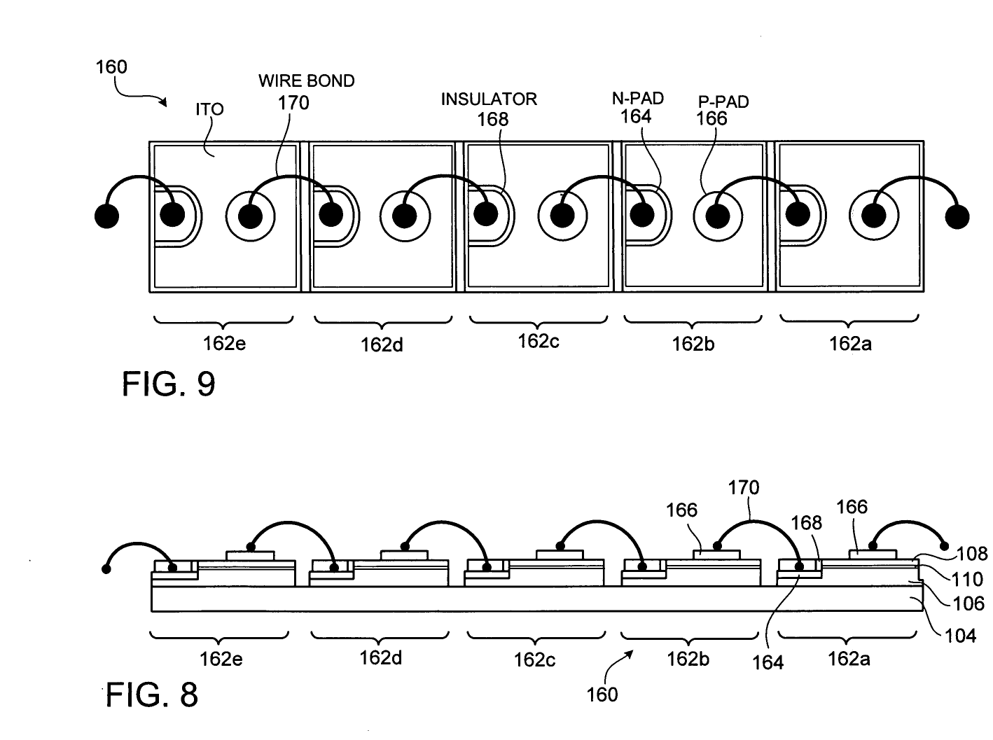

FIG. 8 is a cross sectional diagram of an LED module 160 in which five LED chips 162a to 162e (collectively referred to as 162) are connected in series. The LED chips 162 are all fabricated on a common substrate 104. Each LED chip 162 includes one or more layers of n-type semiconductor material 106 and one or more layers of p-type semiconductor material 108. P-n junctions 110 are formed between the layers 106 and 108. The p-n junctions 110 emit light when electric currents flow through.

For each LED chip 162, in order to form a contact to the n-type semiconductor material 106, a portion of the p-type semiconductor material 108 is etched away to expose the n-type semiconductor material 106. The exposed n-type semiconductor material 106 is partially etched away to provide an area for a metal contact pad, referred to as an N-pad 164. Portions of the n-type material 106 between adjacent LED chips 162 are etched away to isolate the chips 162 so that electric currents do not leak from one chip 162 to another chip through the n-type material 106. The N-pad 164 is formed on the n-type semiconductor material 106. A metal contact pad, referred to as a P-pad 166, is formed above the p-type semiconductor material 108. An insulation material 168 isolates the N-pad 164 from the p-type semiconductor material 108.

A metal bonding wire 170 connects the N-pad 164 of an LED chip 162 to the P-pad 166 of an adjacent LED chip 162. The wire 170 can be made of, e.g., gold. The P-pad 166 of the LED chip 162a and the N-pad 164 of the LED chip 162e are used to connect to external components, such as power lines or other LED modules.

FIG. 9 is a top view of the LED module 160 of FIG. 8. In each LED chip 162, an indium-tin-oxide (ITO) transparent conducting layer covers the portion of the p-type material 108 that has not be etched away. The ITO layer spreads the current more evenly through the p-type material 108.

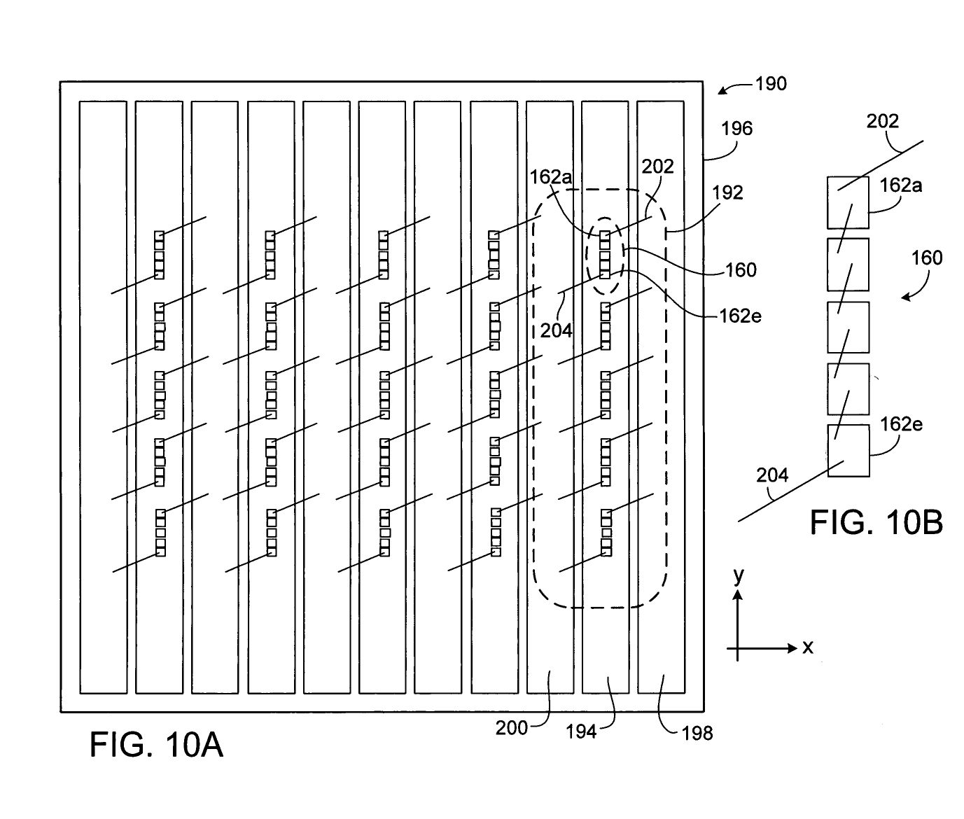

FIG. 10A is a diagram of an example of an LED matrix 190 that includes multiple groups 192 of LED modules 160 mounted on a circuit board 196. Different groups 192 are connected in series, while each group 192 has LED modules 160 that are connected in parallel. Each LED module 160 has five LED chips 162 that are connected in series, similar to the configuration shown in FIG. 8.

Each group 192 has twenty-five LED chips 162 (belonging to five LED modules 160) that are positioned lengthwise in the y-direction along an elongated packaging board 194, forming a line light source. The LED matrix 190 includes five groups 192 that form five line light sources. In each LED module 160, the LED chips 162a and 162e are connected to conducting lines 198 and 200 through bonding wires 202 and 204, respectively. The conducting lines 198 and 200 extend in the y-direction parallel to the lengthwise direction of the elongated packaging board 194.

FIG. 10B is a diagram of the LED chips 162a to 162e of an LED module 160 and the bonding wires (e.g., 202 and 204) that connect to the LED chips 162a to 162e.

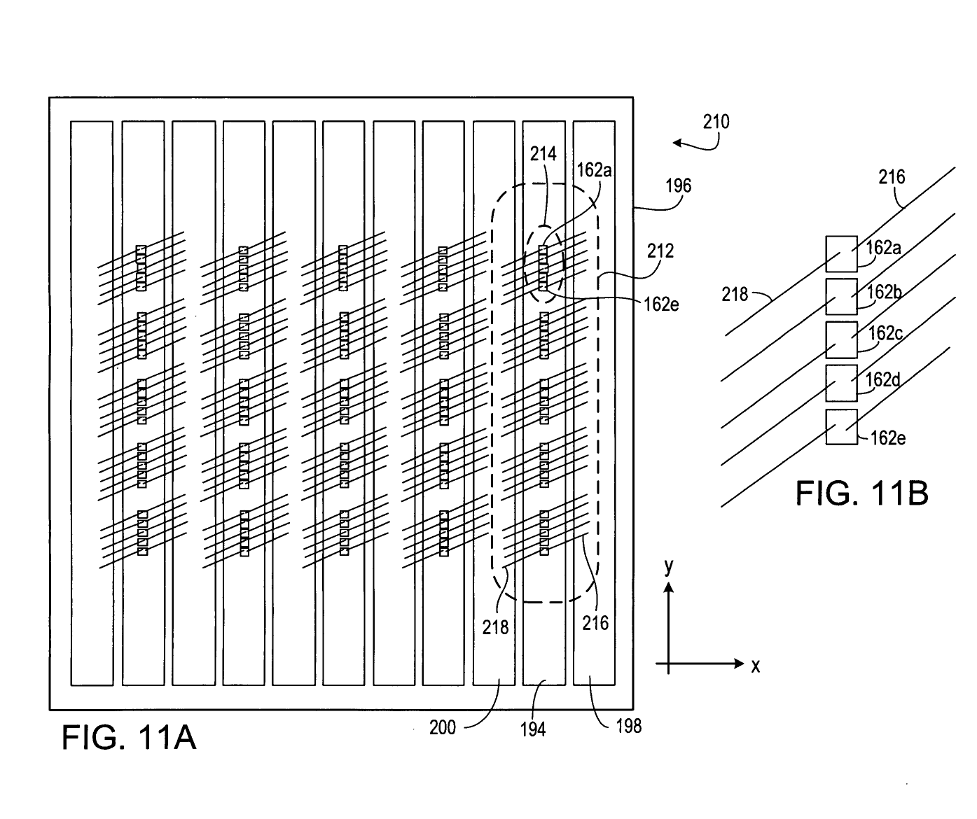

FIG. 11A is a diagram of an example of an LED matrix 210 that includes groups 212 of LED modules 214 that are mounted on a circuit board 196. Different groups 212 are connected in series, while different modules 214 within a group 212 are connected in parallel. In FIG. 11A, each group 212 has twenty-five LED chips 162 that are positioned in the y-direction along an elongated packaging board 194, forming a line light source. The LED matrix 210 includes five groups 212 that form five line light sources in parallel.

The LED chips 162 in FIG. 11A are similar to those in FIG. 10A, except there are no bonding wires connecting one LED chip 162 to another in series. In FIG. 11A, the five LED chips 162 of an LED module 214 are connected in parallel. Each LED chip 162 is connected through bonding wires 216 and 218 to conducting lines 198 and 200, respectively, positioned on two sides of the packaging board 194.

FIG. 11B is a diagram of the LED chips 162 of an LED module 214 and the bonding wires 216 and 218 that connect to the LED chips 162.

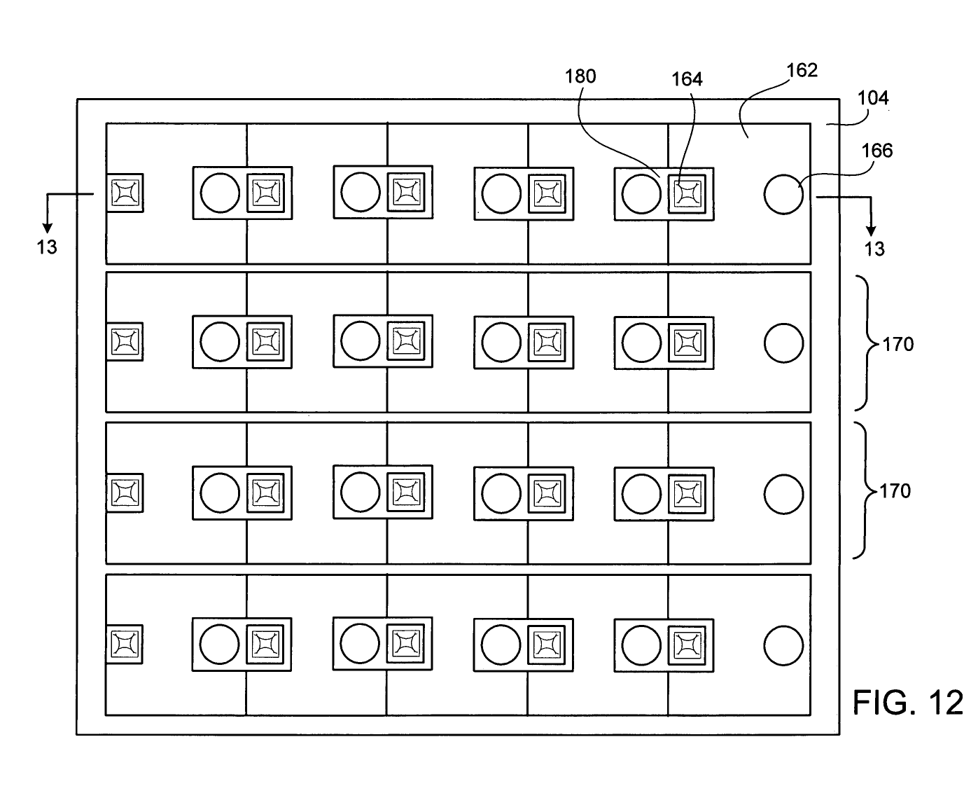

FIG. 12 is a diagram of an example of LED modules 170 each having LED chips 162 connected in series, similar to those shown in FIG. 8. The difference between the LED modules 170 of FIG. 12 and the LED modules 160 of FIG. 8 is that, in the LED module 170, a metal conducting layer 180 is formed above the N-pad 164 of one LED chip and the P-pad 166 of another LED chip to connect the two LED chips 162 together.

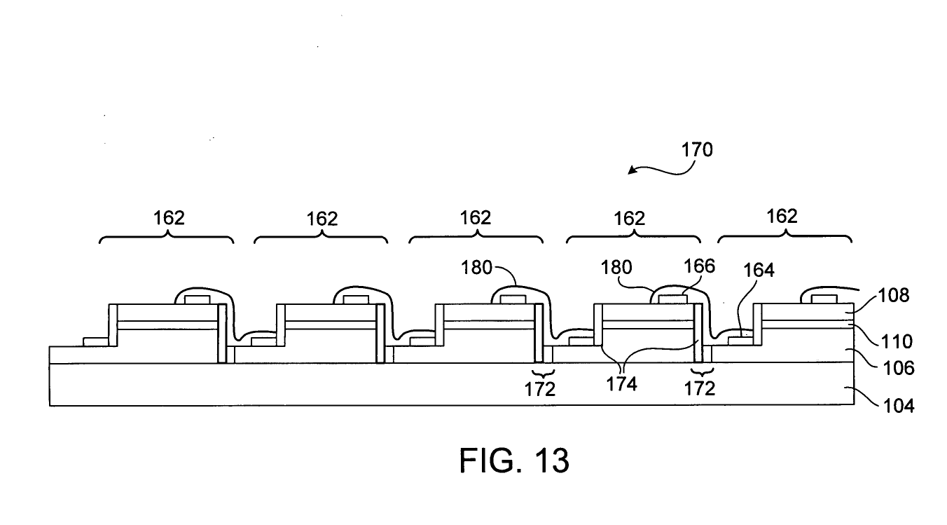

FIG. 13 is a diagram of a cross sectional diagram of an LED module 170. Portions of the n-type material 106 between LED chips 162 are etched away to form gaps 172 to prevent leakage current from flowing from one chip 162 to another through the n-type material 106. Vertical insulation sidewalls 174 are formed to provide electrical isolation between the p-type material 108 and the n-type material 106 at the edges of the p-type and n-type materials.

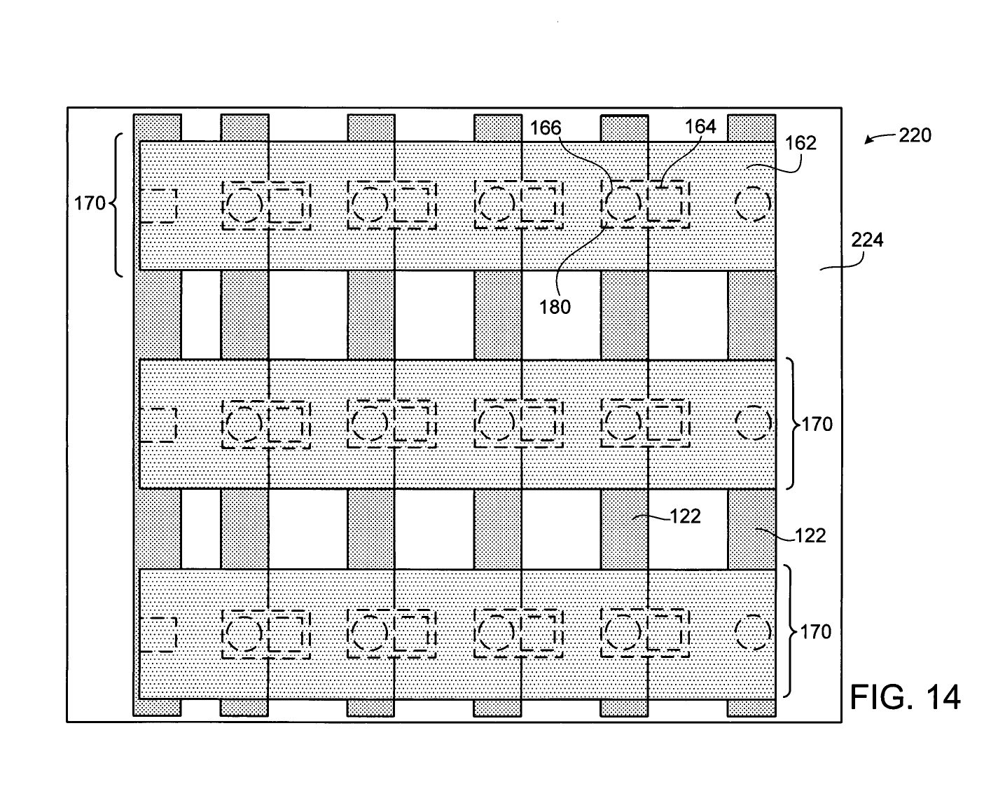

FIG. 14 is a diagram of an example of an LED matrix 220 that includes LED modules 170 that are flip-chip bonded to a circuit board 224. In FIG. 14, the substrates 104 of the LED modules 170 are on top, while the conducting layers 180 are below the substrates 104 and connected to conducting lines 222 on the circuit board 224. FIG. 14 shows six conducting lines 222 in the LED matrix 220. The four conducting lines 222 in the middle are optional.

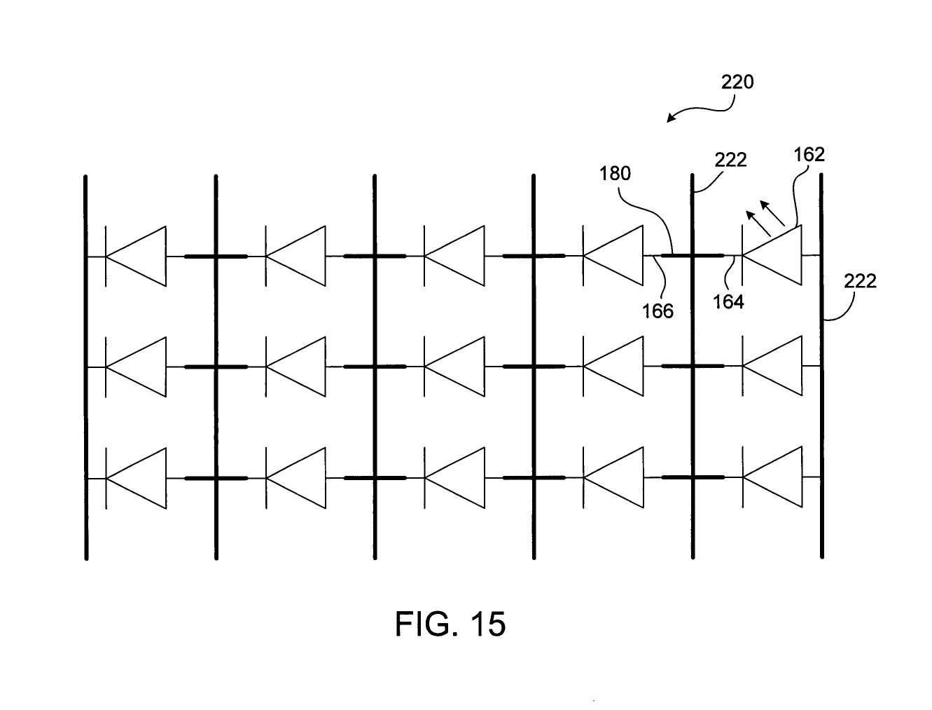

FIG. 15 is a diagram of an equivalent circuit of the LED matrix 220.

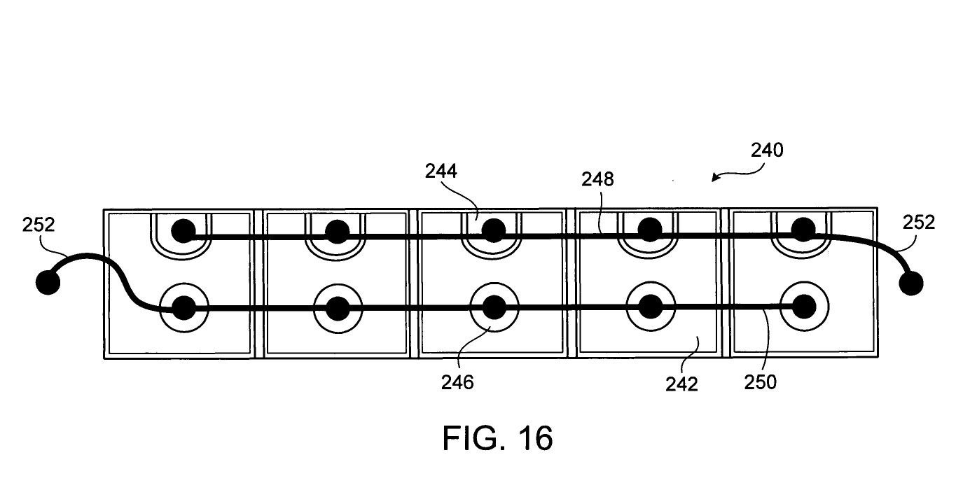

FIG. 16 is a top view of an LED module 240 that includes five LED chips 242 connected in parallel. Each LED chip 242 includes an N-pad 244 connected to the n-type semiconductor material and a P-pad 246 connected to the p-type semiconductor material of the LED chip 242. The N-pads 244 are connected together by metal bonding wires 248, and the P-pads 244 are connected together by metal bonding wires 250. Bonding wires 252 are used to connect to external components, such as a power source or other LED modules.

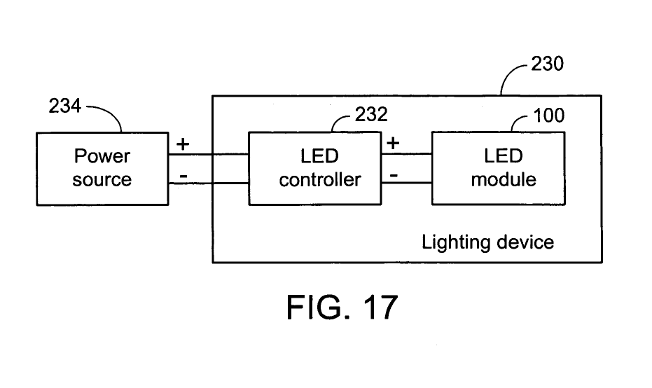

Referring to FIG. 17, the LED module 100 of FIG. 3 (or the large area light sources 130 (FIG. 4), 150 (FIG. 6), 190 (FIG. 10A), 210 (FIG. 11A), and 220 (FIG. 14)) can be used in a lighting device 230 that includes an LED controller 232 for regulating the voltage and current provided to the LED module 100 (or the large area light sources). The lighting device 230 can be packaged according to industry standards (e.g., MR16) so that it can be easily coupled to a standard light bulb socket and connected to a standard voltage provided by a standard power source 234.

It is to be understood that the foregoing description is intended to illustrate and not to limit the scope of the invention, which is defined by the scope of the appended claims. Other embodiments are within the scope of the following claims. For example, in FIG. 4, rather than connecting the LED modules 100 in series, the LED modules 100 can also be connected in parallel, in which the P-pad 116 and N-pad 118 of an LED module 100 is connected to the P-pad 116 and N-pad 118, respectively, of another LED module 100. The number of LED chips that are connected in parallel or series can be different from those described above. The LED chips can be fabricated by forming the p-type material above the substrate, then forming the n-type material above the p-type material. The materials for the n-type semiconductor material, the p-type semiconductor material, the substrate, the conducting layers, the bonding wire, and so forth, can be different from those described above. The LED chips can be designed to emit different colors.

In FIG. 1, the LED chips 102 are arranged in a square or rectangular array. The LED chips 102 can also be arranged in other shapes, such as a triangular, pentagonal, or hexagonal array. In FIGS. 5, 6, 8, 9, 10A, 11A, 12-14, and 16, each LED module has an elongated shape and has LED chips arranged along a line to form a line light source. The LED modules can also have other shapes, in which the LED chips are arranged to form a modular light source having the shape of, e.g., a triangle, square, pentagon, or hexagon.

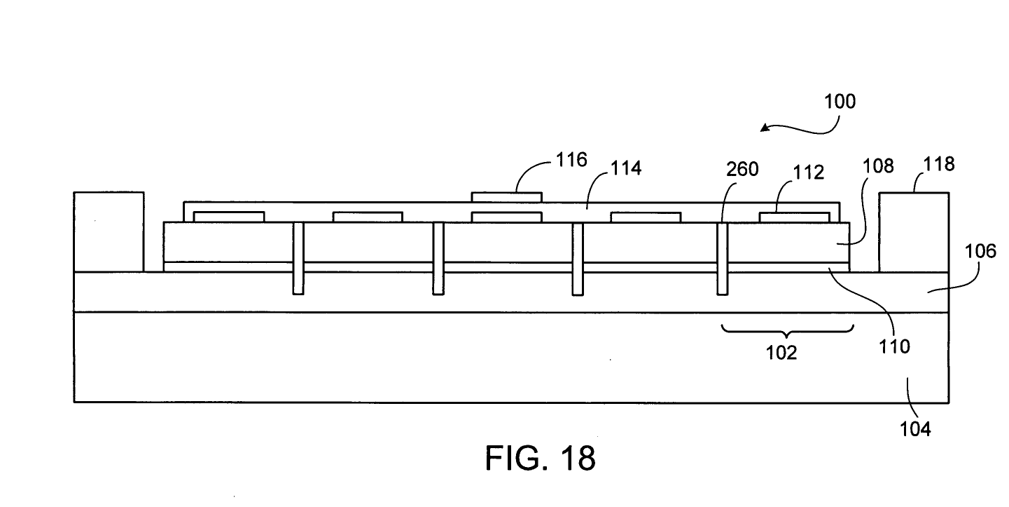

In the LED module 100 of FIGS. 1 and 2, each of the p-type semiconductor material 108 and the n-type semiconductor material 106 is a continuous layer. Referring to FIG. 18, the p-type semiconductor material 108 can also be etched to form distinct regions, so that the p-type semiconductor material 108 in one LED chip 102 is separated from the p-type semiconductor material 108 of another LED chip 102. An insulating material 260 is filled in the space between the p-type semiconductor materials 108 of adjacent LED chips 102 before the conducting layer 114 is formed.

A light source can have a series of parallel arrangements of LED chips that are fabricated on a common substrate. For example, in FIG. 5, the LED modules 140 are separated from one another by etching away the n-type and p-type semiconductor material between the modules, in which the substrate 142 is not cut when operating the LED modules 140. The four LED modules 140 on the common substrate 142 can be connected in series by, e.g., wire bonding or conducting layers. Similarly, several LED modules 160 (FIG. 8) can be fabricated on a common substrate, in which the n-type and p-type semiconductor materials between the modules are etched away to isolate one LED module 160 from another LED module 160 without cutting the common substrate. A first LED module 160 can be connected in series with another LED module 160 by, e.g., wire bonding. The conducting layers can be patterned electrodes that connect the LED chips to form the series and parallel connections. Insulation layers can be used at the edges of the p-type and n-type layers to prevent leakage current. The light source can have an array of LED chips connected together on a common substrate, similar to an integrated circuit. The light source provides high light output and also maintain a low probability of failure.

What is claimed is:

1. An apparatus comprising:
a light emitting diode (LED) module comprising:
a continuous substrate;
a layer of n-type semiconductor material formed above the substrate;
a layer of p-type semiconductor material formed above the n-type semiconductor material, in which a p-n junction is formed between the p-type and n-type semiconductor materials, the p-type and n-type semiconductor materials selected to emit light at the p-n junction when an electric current flows through the p-n junction; and
a plurality of electric contacts connected to the p-type semiconductor material, at least one electric contact connected to the n-type semiconductor material, the electric contacts configured to pass electric current through a plurality of regions in the p-n junction such that the plurality of regions have higher electric current densities and emit light brighter than areas outside of the plurality of regions.

2. The apparatus of claim 1 wherein the electric contacts connected to the p-type semiconductor material are arranged in a plurality of columns and rows such that the LED module forms an area light source.

3. The apparatus of claim 1, further comprising a circuit board having conducting lines, the LED module being flip-chip bonded to the circuit board in which the electric contacts are coupled to the conducting lines.

4. The apparatus of claim 1, further comprising a circuit board having conducting lines, the electric contacts of the LED module being coupled to the conducting lines on the circuit board through bonding wires.

5. The apparatus of claim 1, further comprising a substantially transparent conducting layer that connects two or more of the electric contacts that are connected to the p-type semiconductor material.

6. The apparatus of claim 1 wherein the layer of p-type material comprises distinct regions, each distinct region of the p-type material and a portion of the n-type material in combination forming one of the LED chips.

7. The apparatus of claim 6 wherein the LED module comprises LED chips that are connected in series.

8. The apparatus of claim 7 wherein the layer of p-type material comprises distinct regions, each distinct region of the p-type material and a distinct region of the n-type material in combination forming one of the LED chips.

9. The apparatus of claim 8 wherein the LED module comprises an insulation material to insulate an edge of the n-type material from an edge of the p-type material to reduce leakage current that flows from the p-type material to the n-type material through the edges of the materials.

10. The apparatus of claim 7 wherein the LED chips are connected in series using at least one of bonding wires and conducting layers.

11. The apparatus of claim 6 wherein the LED module comprises at least two LED chips that are connected in parallel.

12. The apparatus of claim 11 wherein the p-type material between LED chips are etched through, and the n-type material between the LED chips are partially etched to expose the n-type material.

13. The apparatus of claim 12 wherein the n-type material belonging to different LED chips are not separated, the n-type material forming a continuous layer.

14. The apparatus of claim 12 wherein the LED module comprises an insulation material to insulate the n-type material from the p-type material at the edges of the n-type and p-type materials exposed by the etching.

15. The apparatus of claim 11 wherein the at least two LED chips are connected in parallel using at least one of bonding wires and conducting layers.

16. The apparatus of claim 1 wherein n-type semiconductor material is deposited on the substrate.

17. An apparatus comprising:
a light emitting diode (LED) module comprising:
a continuous substrate;
a layer of p-type semiconductor material formed above the substrate;
a layer of n-type semiconductor material formed above the p-type semiconductor material, in which a p-n junction is formed between the p-type and n-type semiconductor materials, the p-type and n-type semiconductor materials selected to emit light at the p-n junction when an electric current flows through the p-n junction; and
a plurality of electric contacts connected to the n-type semiconductor material, at least one electric contact connected to the p-type semiconductor material, the electric contacts configured to pass electric current through a plurality of regions in the p-n junction such that the plurality of regions have higher electric current densities and emit light brighter than areas outside of the plurality of regions.

18. A light source comprising:
a circuit board;
a plurality of light emitting diode (LED) modules mounted on the circuit board, each LED module comprising a plurality of LED chips that are positioned adjacent to each other and fabricated on a continuous substrate; and
a housing to enclose the circuit board and the LED modules.

19. The light source of claim 18 wherein the light source complies with MR-16 standard.

20. An apparatus comprising:
a first array of LED chips fabricated on a common substrate, the common substrate that is a continuous piece of material, each LED chip forming a light source and comprising
a layer of p-type semiconductor material,
a layer of n-type semiconductor material coupled to the p-type material to form a p-n junction,
at least one of an electric contact connected to the p-type material and an electric contact connected to the n-type material;
wherein the LED chips of the array are connected in parallel such that the n-type material of the LED chips are electrically coupled together, and the p-type material of the LED chips are electrically coupled together.

21. The apparatus of claim 20, further comprising a circuit board having conducting lines, the first array of LED chips being flip-chip bonded to the circuit board in which the conducting pads of the LED chips are electrically coupled to the conducting lines.

22. The apparatus of claim 21, further comprising a second array of LED chips fabricated on a common substrate that is a continuous piece of material, the second array of LED chips being connected to the first array of LED chips in series.

23. An apparatus comprising:
a first group of light emitting diode (LED) modules connected in parallel, each LED module comprising a plurality of LED chips connected in series, in which the plurality of LED chips in each LED module are fabricated on a common substrate, the common substrate being intact without being divided to separate the LED chips, and for each of the LED modules, the LED chips of the module emit light simultaneously when an electric current passes through the LED module.

24. The apparatus of claim 23 wherein the plurality of LED chips are connected in series by connecting an n-type semiconductor material of one of the LED chips to a p-type semiconductor material of another of the LED chips using at least one of bonding wires and conducting layers.

25. The apparatus of claim 23, further comprising a second group of LED modules connected in parallel, each LED module in the second group comprising a plurality of LED chips connected in series, the second group being connected in series to the first group.

26. The apparatus of claim 25, further comprising an elongated substrate, the plurality of LED chips in the first group being positioned along a lengthwise direction on the first elongated substrate to form a line light source.

27. An apparatus comprising:
a first group of LED modules that are connected in parallel, each LED module comprising a plurality of LED chips connected in parallel, the plurality of LED chips of the LED module being fabricated on a common substrate, the common substrate being intact without being divided to separate the LED chips, the plurality of LED chips emitting light simultaneously when an electric current passes through the LED module.

28. The apparatus of claim 27, further comprising an elongated substrate, the plurality of LED chips in the first group of LED modules being positioned along a lengthwise direction on the elongated substrate to form a line light source.

29. The apparatus of claim 27, further comprising a second group of LED modules that are connected in parallel, each LED module comprising a plurality of LED chips connected in parallel, the second group being connected in series with the first group.

30. A lighting device comprising:
a circuit board having signal lines;
a light emitting diode (LED) module mounted on the circuit board to receive electric power from the signal lines, the LED module comprising a plurality of LED chips fabricated on a common substrate, the common substrate being intact without being cut to separate the LED chips, each LED chip forming a light source, the LED chips being connected in series or parallel; and
a controller to control the LED module.

31. The light source of claim 30 wherein the LED chips of the LED modules are arranged in a plurality of rows and columns to form an area light source.

32. A method comprising:
fabricating a light emitting diode (LED) module that comprises a plurality of LED chips on a continuous substrate, the LED chips being fabricated according to a process comprising:
fabricating a layer of n-type semiconductor material above the substrate;
fabricating a layer of p-type semiconductor material above the n-type semiconductor material, and forming a p-n junction between the p-type and n-type materials, the p-type and n-type materials selected to emit light at the p-n junction when an electric current flows through the p-n junction;
fabricating a plurality of electric contact pads connected to the p-type material; and
fabricating at least one electric contact pad connected to the n-type material, the electric contact pads connected to the p-type and n-type materials configured to pass electric current through a plurality of regions in the p-n junction such that the plurality of regions have higher electric current densities and emit light brighter than areas outside of the plurality of regions.

33. The method of claim 32, further comprising flip-chip bonding the LED module to a circuit board having conducting lines by coupling the electric contact pads to conducting lines on the circuit board.

34. The method of claim 32, further comprising coupling electric contact pads of the LED module to conducting lines on a circuit board through bonding wires.

35. The method of claim 32 wherein fabricating the LED module comprises separating the p-type materials of different LED chips by etching portions of the p-type material to expose the underlying n-type material, the n-type material belonging to different LED chips of the LED module being a continuous layer.

36. The method of claim 35 wherein fabricating the LED module comprises connecting the LED chips in parallel.

37. The method of claim 35 wherein fabricating the LED module comprises fabricating an insulation material positioned between the exposed n-type material and an edge of the p-type material.

38. The method of claim 37 wherein the insulation material is configured to prevent current from flowing from the p-type material to the n-type material through the edge of the p-type material.

39. The method of claim 32 wherein fabricating the LED module comprises separating the p-type and n-type materials of different LED chips by etching portions of the p-type and n-type materials to expose the underlying substrate.

40. The method of claim 39 wherein fabricating the LED module comprises connecting the LED chips in series.

41. The method of claim 39 further comprising fabricating an insulation material positioned adjacent to the edges of the n-type and p-type materials that are exposed by the etching.

42. The method of claim 32 wherein fabricating the layer of n-type semiconductor material above the substrate comprises depositing the n-type semiconductor material on the substrate.

43. A method of operating a lighting device comprising:
passing an electric current through a plurality of light emitting diode (LED) chips that are fabricated on a common substrate that is a continuous piece of material, each LED chip forming a light source, the LED chips being connected in series or parallel, the plurality of LED chips forming a line light source or an area light source; and
regulating the electric current to control a brightness of light emitted by the LED chips.

44. The method of claim 43 wherein passing an electric current through a plurality of LED chips comprises passing the electric current through separated regions of a layer of p-type semiconductor material and different portions of a continuous layer of n-type semiconductor material.

45. A method comprising:
generating light from a plurality of light emitting diode (LED) chips that are positioned adjacent to each other and fabricated on a common substrate that is intact without being cut to separate the LED chips.

46. The method of claim 45 wherein the plurality of LED chips comprise a layer of p-type semiconductor material divided into separate regions and a continuous layer of n-type semiconductor material.
